(19) United States
(12) Patent Application Publication
(10) Pub. No.: US 2026/0033032 A1
(43) Pub. Date: Jan. 29, 2026

(54) IMAGE SENSOR

(71) Applicant: Samsung Electronics Co., Ltd., Suwon-si (KR)

(72) Inventors: Dong Hyun KIM, Suwon-si (KR); Sung Soo CHOI, Suwon-si (KR); Jung Ho AHN, Suwon-si (KR); Dong Chul LEE, Suwon-si (KR)

(73) Assignee: Samsung Electronics Co., Ltd., Suwon-si (KR)

(21) Appl. No.: 19/183,036

(22) Filed: Apr. 18, 2025

(30) Foreign Application Priority Data
Jul. 25, 2024 (KR) 10-2024-0098290

(51) Int. Cl. H10F 39/00

(52) U.S. Cl. CPC H10F 39/807; H10F 39/802

(57) ABSTRACT

An image sensor includes a substrate, a photoelectric conversion region inside the substrate, a first active pattern protruding from a surface of the substrate, an element isolation pattern covering at least a part of a side face of the first active pattern, a first gate electrode on the first active pattern and the element isolation pattern, a lower face of the first gate electrode being lower than an upper face of the first active pattern, a first source/drain region inside the first active pattern adjacent to one face of the first gate electrode and a second source/drain region inside the first active pattern adjacent to the other face of the first gate electrode. A first depth of the first source/drain region is greater than a second depth of the second source/drain region from an upper surface of the first active pattern.

### CROSS-REFERENCE TO THE RELATED APPLICATION

This application claims priority from Korean Patent Application No. 10-2024-0098290 filed on Jul. 25, 2024 in the Korean Intellectual Property Office and all the benefits accruing therefrom under 35 U.S.C. 119, the contents of which in its entirety are herein incorporated by reference.

### BACKGROUND

Some example embodiments relate to an image sensor and/a method for fabricating the same. More specifically, the some example embodiments relate to a CMOS (Complementary Metal-Oxide Semiconductor) image sensor and/a method for fabricating the same.

An image sensor is or includes semiconductor elements that convert optical information into an electric signal. An image sensor may include one or more of a charge coupled device (CCD) image sensor and a CMOS (Complementary Metal-Oxide Semiconductor) image sensor.

The image sensor may be configured in the form of a package. At this time, the package may be formed by a configuration which protects or at least partially protects the image sensor and allows light to enter a photo-receiving surface or a sensing region of the image sensor.

### SUMMARY

Some example embodiments may provide an image sensor having improved performance.

Alternatively or additionally, some example embodiments may provide a method for fabricating an image sensor having improved performance.

According to some example embodiments, there is provided an image sensor comprising a substrate, a photoelectric conversion region inside the substrate, a first active pattern protruding from a surface of the substrate, an element isolation pattern covering at least a part of a side face of the first active pattern, a first gate electrode on the first active pattern and the element isolation pattern, a lower face of the first gate electrode being lower than an upper face of the first active pattern, a first source/drain region inside the first active pattern adjacent to one face of the first gate electrode and a second source/drain region inside the first active pattern adjacent to another face of the first gate electrode. A first depth of the first source/drain region is greater than a second depth of the second source/drain region on the basis of an upper face of the first active pattern.

Alternatively or additionally according to some example embodiments, there is provided an image sensor comprising a substrate, a photoelectric conversion region inside the substrate, a first active pattern protruding from an surface of the substrate, an element isolation pattern covering at least a part of a side face of the first active pattern, a first gate electrode on the first active pattern and the element isolation pattern, a lower face of being lower than an upper face of the first active pattern, a first source/drain region inside the first active pattern adjacent to one face of the first gate electrode and a second source/drain region inside the first active pattern adjacent to another face of the first gate electrode. The first source/drain region comprises an upper doped region having a first depth based on the upper face of the first active pattern, and a lower doped region having a second depth greater than the first depth based on the upper face of the first active pattern. The upper doped region and the lower doped region are different from each other in at least one of a type of majority impurities or a concentration of majority impurities.

Alternatively or additionally according to some example embodiments, there is provided an image sensor comprising a substrate including a first side and a second side opposite to each other, a pixel isolation pattern defining a unit pixel inside the substrate, a photoelectric conversion region inside the unit pixel, an element isolation pattern in contact with the first side of the substrate, and defining a first active pattern inside the unit pixel, a first recess having a lower face lower than an upper face of the first active pattern, inside the element isolation pattern, a first gate electrode filling the first recess on the first active pattern, a first source/drain region inside the first active pattern adjacent to one face of the first gate electrode and a second source/drain region inside the first active pattern adjacent to another face of the first gate electrode. A first depth of the first source/drain region is greater than a second depth of the second source/drain region, on the basis of the upper face of the first active pattern.

However, aspects of some example embodiments are not restricted to the one set forth herein. The above and other aspects of some example embodiments will become more apparent to one of ordinary skill in the art to which some example embodiments pertains by referencing the detailed description given below.

### BRIEF DESCRIPTION OF DRAWINGS

The above and other aspects and features will become more apparent by describing in detail some example embodiments thereof with reference to the attached drawings, in which:

FIG. 1 is an example circuit diagram for explaining an image sensor according to some example embodiments.

FIG. 2 is a cross-sectional view for explaining an image sensor according to some example embodiments.

FIGS. 3A to 3C are enlarged views of a portion P1 of FIG. 2 according to another embodiment.

FIG. 4 is a cross-sectional view for explaining an image sensor according to some example embodiments.

FIG. 5 is an enlarged view of a portion P2 of FIG. 4 according to some example embodiments.

FIG. 6 is a cross-sectional view for explaining an image sensor according to some example embodiments.

FIG. 7 is a plan view for explaining an image sensor according to some example embodiments.

FIG. 8 is a schematic cross-sectional view taken along A-A′ of FIG. 7.

FIG. 9 is a plan view for explaining an image sensor according to some example embodiments.

FIG. 10 is a schematic cross-sectional view taken along A-A′ of FIG. 9.

FIG. 11 is a plan view for explaining an image sensor according to some example embodiments.

FIG. 12 is a schematic cross-sectional view taken along line A-A′ of FIG. 11.

FIG. 13 is a plan view for explaining an image sensor according to some example embodiments.

FIG. 14 is a schematic cross-sectional view taken along line A-A′ of FIG. 13.

FIG. 15 is a plan view for explaining an image sensor according to some example embodiments.

FIGS. 16A to 20B are cross-sectional views for explaining a method for fabricating an image sensor according to some example embodiments.

### DETAILED DESCRIPTION

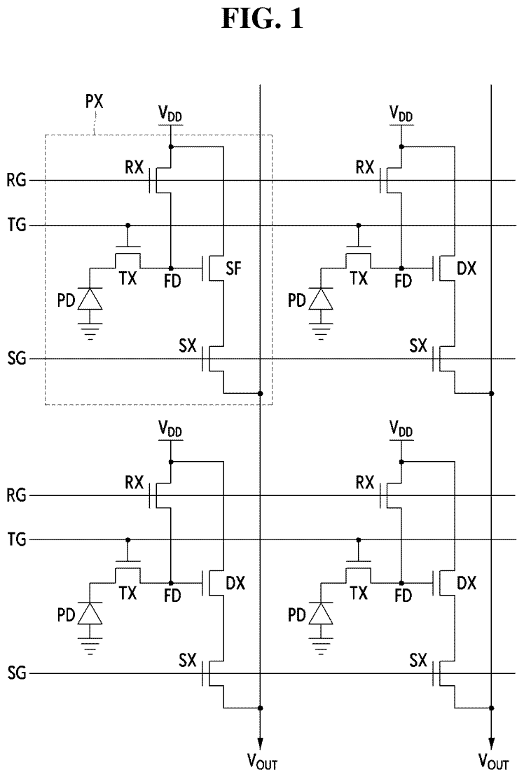

FIG. 1 is a circuit diagram for explaining an image sensor according to some example embodiments.

A photoelectric conversion element PD may generate electric charges in proportion to an amount of light that is incident from the outside. The photoelectric conversion element PD may be or may include a photodiode; example embodiments are not limited thereto. The photoelectric conversion element PD may be coupled with a transfer transistor TX, which transfers the generated and accumulated electric charges to a floating diffusion region FD. Since the floating diffusion region FD is a region which converts the electric charges into a voltage, and has a parasitic capacitance, the electric charges may be accumulatively stored therein.

One end of the transfer transistor TX may be connected to the photoelectric conversion element PD, and another end of the transfer transistor TX may be connected to the floating diffusion region FD. The transfer transistor TX may be formed by a transistor that is driven by a bias, such as a dynamically determined bias or, alternatively, a predetermined bias (e.g., a transfer signal TG). For example, the transfer transistor TX may transmit the electric charges, which are generated from the photoelectric conversion element PD, to the floating diffusion region FD in accordance with the transfer signal TG.

The source follower transistor SF may amplify a change in electrical potential of the floating diffusion region FD to which the electric charges are sent from the photoelectric conversion element PD and output it to an output line VOUT. When the source follower transistor SF is turned on, an electrical potential such as a predetermined electrical potential provided to a drain of the source follower transistor SF, for example, a power supply voltage VDD, may be sent to a drain region of a selection transistor SX.

The selection transistor SX may select a unit pixel to be read, e.g., based on a row basis. The selection transistor SX may be made up of a transistor that is driven by a selection line that applies a bias, such as but not limited to a predetermined bias (e.g., a row selection signal SX).

A reset transistor RX may periodically reset the floating diffusion region FD. The reset transistor RX may be made up of a transistor that is driven by a reset line that applies a bias, such as but not limited to a predetermined bias (e.g., a reset signal RG). When the reset transistor RX is turned on by the reset signal RG, an electrical signal such as a predetermined electrical potential provided to the drain of the reset transistor RX, for example, the power supply voltage VDD, may be sent to the floating diffusion region FD to reset the floating diffusion region FD.

Although FIG. 1 discloses that each unit pixel PX includes four pixel transistors TX, RX, SF, and SX, example embodiments are not limited thereto, and the number of pixel transistors in each unit pixel PX may vary.

Further, each of the transistors such as each of the reset signal RG, the transfer signal TX, the source follower transistor SF, and the selection transistor SX may be planar nMOS transistors, and/or each may have the same electrical and/or physical properties as one another; however, example embodiments are not limited thereto. For example, at least one of the reset signal RG, the transfer signal TX, the source follower transistor SF, and the selection transistor SX may be a pMOS transistor and/or may not be a planar transistor, and/or may have electrical and/or physical properties different from at least one other of the of the reset signal RG, the transfer signal TX, the source follower transistor SF, and the selection transistor SX; example embodiments are not limited thereto.

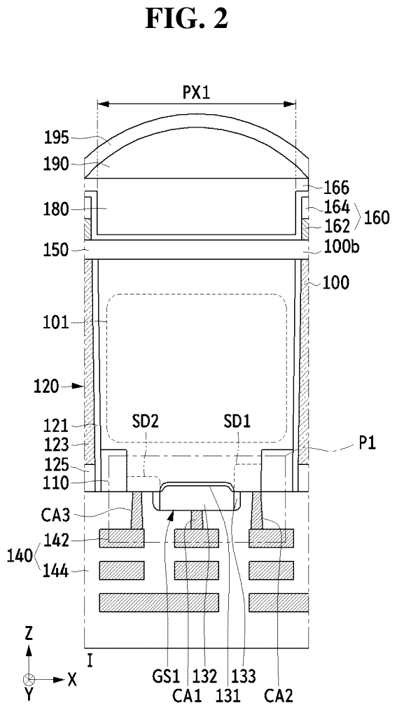

FIG. 2 is a cross-sectional view for explaining an image sensor according to some example embodiments.

Referring to FIG. 2, the image sensor according to some example embodiments includes a first substrate 100, a photoelectric conversion region 101, an element isolation pattern 110, a pixel isolation pattern 120, a first gate structure GS1, a first wiring structure 140, a surface insulating film 150, a grid film 160, a color filter 180, and a microlens 190.

The first substrate 100 may be or may include a semiconductor substrate. For example, the first substrate 100 may be or include bulk silicon or silicon-on-insulator (SOI). The first substrate 100 may be a silicon substrate such as a single-crystal silicon substrate, and/or may include other materials, for example, one or more of silicon germanium, indium antimonide, lead telluride, indium arsenide, indium phosphide, gallium arsenide or gallium antimonide. Alternatively or additionally, the first substrate 100 may be one having an epitaxial layer formed on a base substrate.

The first substrate 100 may include a first side 100a and a second side 100b that are opposite to each other. In some example embodiments, the first side 100a may be referred to as a front side of the first substrate 100, and the second side 100b may be referred to as a back side of the first substrate 100; however, example embodiments are not limited thereto. In some example embodiments, the second side 100b of the first substrate 100 may be a photo-receiving surface on which light is incident. For example, the image sensor according to some example embodiments may be a back-illuminated (BSI) image sensor.

In some example embodiments, the first substrate 100 may include impurities of a first conductivity type. Although the first conductivity type is described as a p-type, this is merely by way of example, and the first conductivity type may be an n-type.

The photoelectric conversion region 101 may be formed inside the first substrate 100. The photoelectric conversion region 101 may be formed inside a unit pixel PX arranged inside the first substrate 100. For example, a plurality of photoelectric conversion regions 101 corresponding to a plurality of unit pixels PX may be arranged two-dimensionally (for example, in the form of a matrix) inside the first substrate 100.

The photoelectric conversion region 101 may have a second conductivity type different from the first conductivity type. For example, the photoelectric conversion region 101 may be formed by ion-implantation and/or diffusion of n-type impurities into the p-type first substrate 100. The photoelectric conversion region 101 and a region of the first substrate 100 that surrounds it may be provided as the photoelectric conversion element PD of FIG. 1. In some example embodiments, a concentration of n-type impurities included in the photoelectric conversion region 101 may be greater than, e.g., greater by an order of magnitude or more than, a concentration of p-type impurities included in the first substrate 100; example embodiments are not limited thereto.

The element isolation pattern 110 may be formed inside the first substrate 100. The element isolation pattern 110 may be adjacent to (or in contact with) the first side 100a of the first substrate 100. The element isolation pattern 110 may define an active pattern AR inside the unit pixel PX adjacent to the first side 100a. For example, a shallow trench (hereinafter, an element isolation trench) that extends from the first side 100a to define the active pattern AR may be formed inside the first substrate 100. The element isolation pattern 110 may fill at least a part of the element isolation trench.

The element isolation pattern 110 may include an insulating material, for example, but not limited to, at least one of silicon oxide, silicon nitride, silicon oxynitride or a combination thereof. For example, the element isolation pattern 110 may include a silicon oxide film. Although the element isolation pattern 110 is shown as being a single film, this is merely by way of example, and the element isolation pattern 110 may be or may include a multi-layer film.

The pixel isolation pattern 120 may be formed inside the first substrate 100. The pixel isolation pattern 120 may define a plurality of unit pixels PX inside the first substrate 100. For example, a deep trench (hereinafter, a pixel isolation trench) that defines a plurality of unit pixels PX may be formed inside the first substrate 100. For example, the pixel isolation trench may be formed in a lattice shape from a planar viewpoint (e.g., an XY plane) and may surround each unit pixel PX. The pixel isolation pattern 120 may fill all of or at least a part of the pixel isolation trench.

The pixel isolation pattern 120 may prevent or reduce photocharges, e.g., electron-hole pairs, generated in a specific unit pixel from moving to adjacent other unit pixels due to a random drift. Furthermore, the pixel isolation pattern 120 may prevent or reduce an optical cross-talk in which light incident on a specific unit pixel is incident on other adjacent unit pixels.

In some example embodiments, a width of the pixel isolation pattern 120 may decrease from the first side 100a to the second side 100b. Here, the width of the pixel isolation pattern 120 indicates a width measured along a first direction (e.g., an X direction of FIG. 2). This may be due or at least partially due to the fact that the etching process for forming the pixel isolation pattern 120 is performed toward the first side 100a of the first substrate 100; this etching process may not be fully anisotropic and may have a tapering effect, for example. For example, the pixel isolation pattern 120 may be a FDTI (frontside DTI) formed by a DTI (deep trench isolation) process on the front side (e.g., the first side 100a) of the first substrate 100.

In some example embodiments, the pixel isolation pattern 120 may include a liner insulating film 121, a gap fill conductive film 123, and a buried insulating film 125.

The liner insulating film 121 may be stacked on the inner wall of the first substrate 100. The liner insulating film 121 may be interposed between the first substrate 100 and the gap fill conductive film 123. For example, the liner insulating film 121 may conformally extend along a profile of an inner wall of the first substrate 100.

The liner insulating film 121 may include an insulating material, for example, but not limited to, at least one of silicon oxide, silicon nitride, silicon oxynitride, silicon carbonitride, silicon oxycarbonitride or a combination thereof. Although the liner insulating film 121 is only shown as being a single film, this is merely an example, and the liner insulating film 121 may be or may include a multi-layer film. Although a boundary or interface between the element isolation pattern 110 and the liner insulating film 121 is shown to exist, this is merely an example, and the boundary between the element isolation pattern 110 and the liner insulating film 121 may not exist. For example, if the element isolation pattern 110 and the liner insulating film 121 include the same material (e.g., silicon oxide film), the boundary or interface between the element isolation pattern 110 and the liner insulating film 121 may not be distinguished.

The gap fill conductive film 123 may be stacked on the liner insulating film 121. The gap fill conductive film 123 may fill at least a part of a region of the pixel isolation pattern 120 that remains after the liner insulating film 121 is filled. In some example embodiments, the gap fill conductive film 123 may be spaced apart from the first side 100a, and may be in contact with the second side 100b.

The gap fill conductive film 123 may include a conductive material, for example, but not limited to, at least one of an undoped and polysilicon film, an undoped silicon germanium film, an impurity-doped polysilicon film, an impurity-doped silicon germanium film or a metal film. As an example, the gap fill conductive film 123 may include a polysilicon film doped with a p-type impurity (e.g., boron (B)) and/or an n-type impurity (e.g., phosphorus (P) and/or arsenic (As)).

In some example embodiments, a negative (−) bias voltage may be applied to the gap fill conductive film 123. Such a gap fill conductive film 123 may capture holes that may exist on the surface of the first substrate 100 adjacent to the pixel isolation pattern 120, thereby improving dark current characteristics of the image sensor.

The buried insulating film 125 may be stacked on the liner insulating film 121 and the buried insulating film 125. The gap fill conductive film 123 may be spaced apart from the first side 100a by the buried insulating film 125. In some example embodiments, a part of the liner insulating film 121 may be interposed between the element isolation pattern 110 and the buried insulating film 125.

A depth at which the buried insulating film 125 is formed is shown as being the same as a depth at which the element isolation pattern 110 is formed on the basis of the first side 100a, but this is merely an example, and the depth at which the buried insulating film 125 is formed may be different from the depth at which the element isolation pattern 110 is formed.

The buried insulating film 125 may include an insulating material, for example, but not limited to, at least one of silicon oxide, silicon nitride, silicon oxynitride or a combination thereof. Although the buried insulating film 125 is shown to be a single film, this is merely an example, and the buried insulating film 125 may be a multi-layer film. Although a boundary between the liner insulating film 121 and the buried insulating film 125 is shown to exist, this is merely an example, and the boundary between the liner insulating film 121 and the buried insulating film 125 may not exist. For example, if the liner insulating film 121 and the buried insulating film 125 include the same material (e.g., silicon oxide film), for example by being formed at the same time, the boundary between the liner insulating film 121 and the buried insulating film 125 may not be distinguished.

The first gate structure GS1 may be disposed on and in the first side 100a of the first substrate 100. The first gate structure GS1 may be disposed on and in the active pattern of the first unit pixel PX1. One or more of the shape, size, number, placement, and the like of the first gate structure GS1 are merely an example, and are not limited to those shown in the drawings.

The first gate structure GS1 may include various transistors for processing the electrical signal generated from the unit pixel PX. For example, the first gate structure GS1 may be provided as at least one gate of the reset transistor RX, the source follower transistor SF or the selection transistor SX described above in the description of FIG. 1.

Referring to FIG. 2, the first gate structure GS1 may include a gate dielectric film 131, a gate electrode film 132, and a gate spacer 133.

The gate dielectric film 131 may be interposed between the first substrate 100 and the gate electrode film 132. The gate dielectric film 131 may include a dielectric material, for example, at least one of silicon oxide, silicon oxynitride, silicon nitride or a high dielectric constant material having a higher dielectric constant than silicon oxide. The high-dielectric constant material may include, but not limited to, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

The gate electrode film 132 may be stacked on the gate dielectric film 131. The gate electrode film 132 may include a conductive material, for example, but not limited to, at least one of a metal film, a metal silicide film, an undoped polysilicon film, an undoped silicon germanium film, an impurity-doped polysilicon film or an impurity-doped silicon germanium film. As an example, the gate electrode film 132 may include a polysilicon film doped with n-type impurities.

The gate spacer 133, e.g., the sidewall spacer, may extend along the side face of the gate electrode film 132. The gate spacer 133 may include at least one of an insulating material, for example, but not limited to, silicon oxide, silicon nitride, silicon oxynitride, silicon oxycarbide, silicon boron nitride, silicon boron carbonitride, silicon oxycarbonitride, and combinations thereof.

Referring to FIG. 2, a first source/drain region SD1 may exist at one end of the first gate structure GS1, and a second source/drain region SD2 may exist at the other end of the first gate structure GS1. The first source/drain region SD1 and the second source/drain region SD2 may have the same conductivity type as the photoelectric conversion region 101. For example, the first source/drain region SD1 and the second source/drain region SD2 may be doped with impurities of the same n-type conductivity type as the photoelectric conversion region 101; example embodiments are not limited thereto.

For example, in some example embodiments one the first source/drain region SD1 and the second source/drain region SD2 may be doped with phosphorus and arsenic, and the other of the first source/drain region SD1 and the second source/drain region may be doped with phosphorus without being doped with arsenic, or may be doped with arsenic without being doped with phosphorus; example embodiments are not limited thereto. Alternatively or additionally, one or both of the first source/drain region SD1 and the second source/drain region SD2 may be counterdoped, e.g., may be doped with impurities having opposite conductivity type to one another. For example, the first source/drain region SD1 may be doped with both a majority of n-type impurities and minority of p-type impurities; in some example embodiments, a dopant concentration of n-type impurities may be greater than, e.g., greater by an order of magnitude or more than, a dopant concentration of p-type impurities. Example embodiments are not limited thereto.

The first wiring structure 140 may electrically connect the first gate structure GS1 to other components inside the image sensor. For example, a first contact CA1 that extends in the third direction Z to connect the first gate structure GS1 to the first wiring pattern 142 may be formed. Alternatively or additionally, for example, a second contact CA2 that extends in the third direction Z to connect one of the first source/drain regions SD1 to the first wiring pattern 142 may be formed. Alternatively or additionally, for example, a third contact CA3 that extends in the third direction Z to connect one of the second source/drain regions SD2 to the first wiring pattern 142 may be formed.

The first wiring structure 140 may transmit and/or receive electrical signals to and from other components inside the image sensor through the first contact CA1, the second contact CA2, and/or the third contact CA3. For example, when the first gate structure GS1 is or corresponds to a source follower transistor (SF shown in FIG. 1), the first contact CA1 that connects the first gate structure GS1 and the first wiring pattern 142 may be connected to a photoelectric conversion region (FD shown in FIG. 1) inside the image sensor.

A number of and/or an orientation of and/or a thickness of the first wiring structure 140 is not limited to what is described with reference to FIG. 2.

The first contact CA1, the second contact CA2, and the third contact CA3 may each include a conductive material such as the same or different conductive film, for example, but not limited to, a metal film and/or a metal silicide film.

The surface insulating film 150 may be formed on the second side 100b of the first substrate 100. The surface insulating film 150 may conformally extend along the second side 100b of the first substrate 100. The surface insulating film 150 may include an insulating material, for example, but not limited to, at least one of silicon oxide, silicon nitride, silicon oxynitride, aluminum oxide, hafnium oxide, and combinations thereof.

The surface insulating film 150 is provided as an anti-reflection film, and may prevent or reduce reflection of light incident on the second side 100b, which is the photo-receiving surface. This may improve the photo-receiving rate of the photoelectric conversion region 101. Alternatively or additionally, the surface insulating film 150 is provided as a planarization film, and may contribute to a color filter 180 and a microlens 190 to be described below being formed to a uniform height.

In some example embodiments, the surface insulating film 150 may be formed of a multi-layer film. As an example, unlike the shown example, the surface insulating film 150 may include an aluminum oxide film, a hafnium oxide film, a silicon oxide film, a silicon nitride film, and a hafnium oxide film that are sequentially stacked on the second side 100b of the first substrate 100.

The grid film 160 may be formed on the surface insulating film 150. The grid film 160 may be formed in a lattice shape from a planar viewpoint (e.g., the XY plane). For example, the grid film 160 may be disposed to overlap at least a part of the pixel isolation pattern 120 in the third direction Z.

In some example embodiments, the grid film 160 may include a first grid film 162 and a second grid film 164. The first grid film 162 and the second grid film 164 may be sequentially stacked on the surface insulating film 150.

The first grid film 162 may include, for example, but not limited to, at least one of titanium (Ti), titanium nitride (TiN), tantalum (Ta), tantalum nitride (TaN), tungsten (W), aluminum (Al), copper (Cu), and combinations thereof. The first grid film 162 may prevent or reduce electric charges generated by ESD (electrostatic discharge) or the like from being accumulated on the surface of the first substrate 110 (e.g., the second side 110b) to effectively prevent or reduce an ESD bruise defect.

The second grid film 164 may include a low refractive index material that has a lower refractive index than silicon (Si). For example, the second grid film 164 may include, but not limited to, at least one of silicon oxide, aluminum oxide, tantalum oxide, and combinations thereof. The second grid film 164 may improve the light collection efficiency of each of the unit pixels PX1 to PX6, by refracting or reflecting light obliquely incident on the second side 100b, which is a photo-receiving surface.

The first protective film 166 may be formed on the surface insulating film 150 and the grid film 160. The first protective film 166 may conformally extend along the profiles of the surface insulating film 150 and the grid film 160. The first protective film 166 may prevent or reduce damage of the surface insulating film 150 and the grid film 160. The first protective film 166 may include, for example, but not limited to, aluminum oxide (AlO).

The color filter 180 may be formed on the first protective film 166. The color filter 180 may have various colors depending on the unit pixel. For example, the color filter 180 may include a red filter, a green (PXreen) filter, a blue filter, a yellow filter, a magenta filter, and a cyan filter, and may further include a white filter.

The micro lens 190 may be formed on the color filter 180. The micro lens 190 has a convex shape, and may have a predetermined radius of curvature. Accordingly, the micro lens 190 may collect the light that enters the photoelectric conversion region 101. The micro lens 190 may include, for example, but not limited to, a light-transmitting resin.

The second protective film 195 may be formed on the micro lens 190. The second protective film 195 may extend along the surface of the micro lens 190. The second protective film 195 may include, for example, but not limited to, an inorganic oxide film such as a silicon oxide film, a titanium oxide film, a zirconium oxide film or a hafnium oxide film. As an example, the second protective film 195 may include a low temperature oxide (LTO).

The second protective film 195 may protect or at least partially protect the micro lens 190 from the outside. For example, the second protective film 195 may protect the micro lens 190 containing an organic material, by including an inorganic oxide film. Alternatively or additionally, the second protective film 195 may improve the quality of the image sensor, by improving the light collection efficiency of the micro lens 190. For example, the second protective film 195 may reduce reflection, refraction, scattering, or the like of incident light that reaches the space between the micro lenses 190 by filling the space between the micro lenses 190.

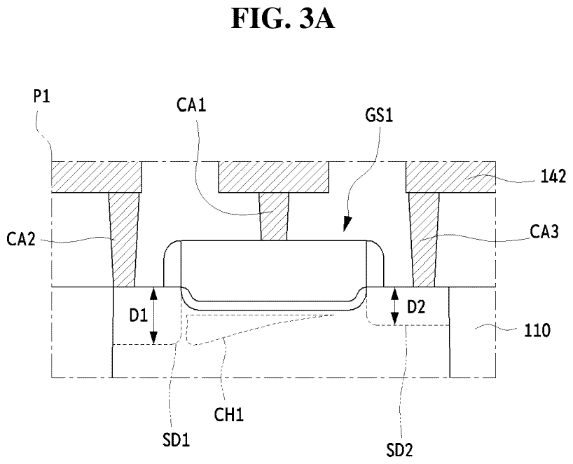

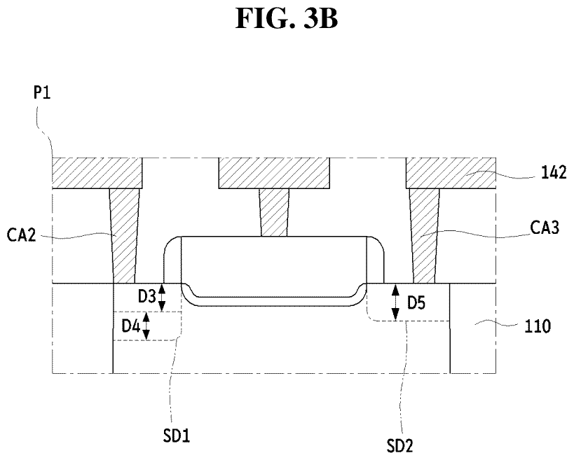

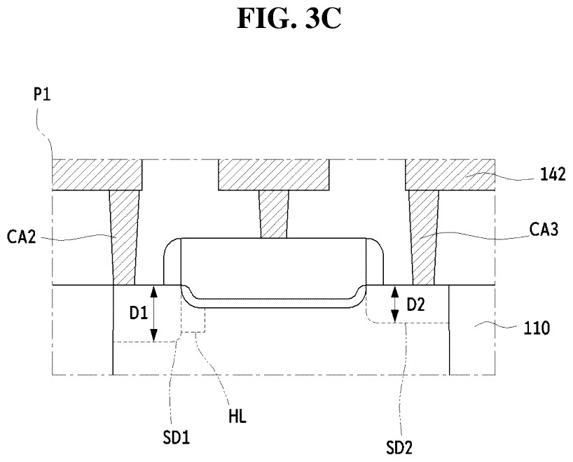

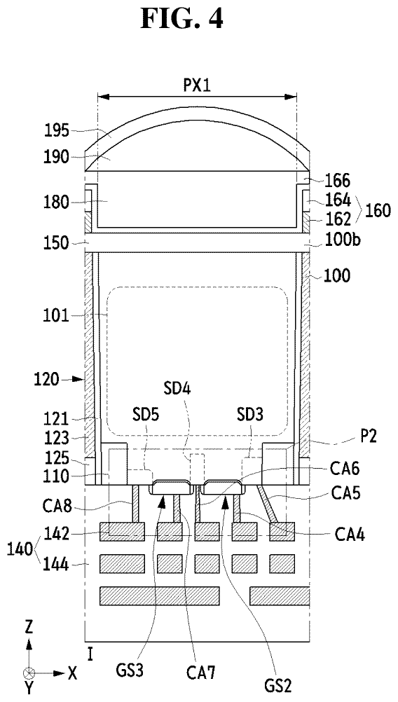

FIGS. 3A to 3C are enlarged views of a portion P1 of FIG. 2 according to another embodiment. For convenience of explanation, differences from the contents explained in FIG. 2 will be mainly explained.

Referring to FIG. 3A, the first source/drain region SD1 located at one end of the first gate structure GS1 may have a first depth D1 from the active pattern of the substrate 100. The second source/drain region SD2 located at the other end of the first gate structure GS1 may have a second depth D2 from the active pattern of the substrate 100. The first source/drain region SD1 may be in contact with the active pattern of the substrate 100. The second source/drain region SD2 may be in contact with the active pattern of the substrate 100. In some example embodiments, the first depth D1 may be greater than the second depth D2. In some example embodiments, the first depth D1 and/or the second depth D2 may be measured, e.g., with various analytical equipment, such as but not limited to secondary ion mass spectrometry (SIMS) and/or electrical measurements and/or dopant decorating techniques and/or scanning electron microscopy (SEM); example embodiments are not limited thereto.

The first source/drain region SD1 and/or the second source/drain region SD2 may include n-type impurities, and may or may not include p-type impurities, e.g., at a concentration much lower than a concentration of n-type impurities. The n-type impurities may include, but not limited to, at least one of phosphorus (P), arsenic (As), antimony (Sb), and bismuth (Bi), and may be the same or different between the first source/drain region SD1 and the second source/drain region SD2.

The first source/drain region SD1 and/or the second source/drain region SD2 may include p-type impurities, and may or may not include n-type impurities, e.g., at a concentration much lower than a concentration of p-type impurities. The p-type impurities may include, but not limited to, at least one of boron (B) and gallium (Ga), and may be the same or different between the first source/drain region SD1 and the second source/drain region SD2.

A first channel CHI may be formed under the first gate structure GS1, for example during electrical operation thereof. The first channel CHI may be formed between the first source/drain region SD1 and the second source/drain region SD2. Since the first depth D1 and the second depth D2 of the first source/drain region SD1 and the second source/drain region SD2 are different, an area of the first channel CHI may increase. This may make it easier to adjust the threshold voltage of the semiconductor device including the first gate structure GS1, and may improve characteristics such as increase in transconductance. An effect of reducing noise in the image sensor may be provided due to the improvement in characteristics of the semiconductor element inside the image sensor.

Referring to FIG. 3B, the first source/drain region SD1 located at one end of the first gate structure GS1 may include an upper doping region and a lower doping region. For example, the upper doped region may be a region having a third depth D3 from the upper face of the active pattern. The upper doped region may be in contact with the active pattern of the substrate 100. The lower doped region may be a region having a fourth depth D4 greater than the third depth D3 on the basis of the upper face of the active pattern. A concentration of impurities the upper doped region may be the same as, or different from (e.g., greater than or less than) a concentration of impurities included in the lower doped region, and in some cases may be the same as, or different from, a concentration of impurities included in the second source/drain region SD2.

In some example embodiments, the upper doped region and the lower doped region may be doped with different types of ions. Different types of ions may refer to, for example, different types of ions inside a first type impurity. For example, if the first type impurity is an n-type impurity, the upper doped region may be doped with phosphorus (P) ions, and the lower doped region may be doped with arsenic (As) ions.

Alternatively or additionally in some example embodiments, the upper doped region and the lower doped region may be doped with different concentrations of ions. Different concentrations of ions may refer to, for example, different concentrations inside the same type of ions.

The second source/drain region SD2 located at the other end of the first gate structure GS1 may be a region having a fifth depth D5 from an upper face of the active pattern of the substrate 100. In some example embodiments, the fourth depth D4 may be greater than the fifth depth D5.

Referring to FIG. 3C, the image sensor according to the present disclosure may further include a first halo region, first pocket region, or first halo region HL1. The first halo region HL1 may be formed inside the active pattern. The first halo region HL1 may be adjacent to the first source/drain region SD1.

The impurity doped in the first halo region HL1 may be a different type of impurity from the impurity doped in the first source/drain region SD1 or the second source/drain region SD2. For example, when the transistor formed on the substrate 100 is a pFET, the first halo region HL1 may include an n-type impurity, and may include, for example, phosphorus (P), arsenic (As), antimony (Sb), or the like. When the transistor formed on the substrate 100 is an nFET, the first halo region HL1 may include a p-type impurity, for example, boron (B). The first halo region HL1 and the first source/drain region SD1 may together correspond to a diode and in some cases the diode may help prevent or reduce leakage current; however, example embodiments are not limited thereto.

FIG. 4 is a cross-sectional view for explaining an image sensor according to some example embodiments. For convenience of explanation, differences will be mainly explained.

Referring to FIG. 4, an image sensor according to some example embodiments includes a first substrate 100, a photoelectric conversion region 101, an element isolation pattern 110, a pixel isolation pattern 120, a second gate structure GS2, a third gate structure GS3, a first wiring structure 140, a surface insulating film 150, a grid film 160, a color filter 180, and a microlens 190.

The second gate structure GS2 and the third gate structure GS3 may be disposed on and in the first active pattern. The second gate structure GS2 and the third gate structure GS3 may be disposed on and in the active pattern of the first unit pixel PX1. One or more of the shapes, sizes, numbers, placements and the like of the second gate structure GS2 and the third gate structure GS3 are merely an example and are not limited to those shown in the drawings.

The second gate structure GS2 or the third gate structure GS3, or both the second gate structure GS2 and the third gate structure GS3, may include various transistors for processing the electrical signal generated from the first unit pixel PX1. For example, the second gate structure GS2 or the third gate structure GS3 may be provided as a gate of at least one of the reset transistor RX, the source follower transistor SF, or the selection transistor SX described above in the description of FIG. 1.

Referring to FIG. 4, a third source/drain region SD3 may exist at one end of the second gate structure GS2, and a fourth source/drain region SD4 may exist at the other end of the second gate structure GS2. A fourth source/drain region SD4 may exist at one end of the third gate structure GS3, and a fifth source/drain region SD5 may exist at the other end of the third gate structure GS3. For example, the second gate structure GS2 and the third gate structure GS3 may share the fourth source/drain region SD4.

Referring to FIG. 4, the first wiring structure 140 may electrically connect the second gate structure GS2 to other components inside the image sensor. For example, a fourth contact CA4 that extends in the third direction Z to connect the second gate structure GS2 and the first wiring pattern 142 may be formed. Alternatively or additionally, for example, a fifth contact CA5 that extends in the third direction Z to connect one of the third source/drain regions SD3 and the first wiring pattern 142 may be formed. Alternatively or additionally, for example, a sixth contact CA6 that extends in the third direction Z to connect one of the fourth source/drain regions SD4 and the first wiring pattern 142 may be formed. Alternatively or additionally, for example, a seventh contact CA7 that extends in the third direction Z to connect one of the second gate structure GS2 and the first wiring pattern 142 may be formed. Alternatively or additionally, for example, an eighth contact CA8 that extends in the third direction Z to connect one of the fifth source/drain regions SD5 and the first wiring pattern 142 may be formed.

Although the fifth contact CA5 is shown extending diagonally with respect to the first direction X and the second direction Y, example embodiments are not limited thereto. For example, the fifth contact CA5 may not extend in a diagonal direction.

The first wiring structure 140 may transmit and receive electrical signals with other configurations inside the image sensor through the fourth contact CA4, the fifth contact CA5, the sixth contact CA6, the seventh contact CA7 and/or the eighth contact CA8. For example, if the second gate structure GS2 is a reset transistor (RX shown in FIG. 1), the first contact CA4 that connects the second gate structure GS2 and the first wiring pattern 142 may be connected to the photoelectric conversion region (FD shown in FIG. 1) inside the image sensor.

The fourth contact CA4, the fifth contact CA5, the sixth contact CA6, the seventh contact CA7 and/or the eighth contact CA8 may each include, but not limited to, a conductive material, for example, a metal film and/or a metal silicide film, and may or may not include the same material and/or may or may not be formed at the same time.

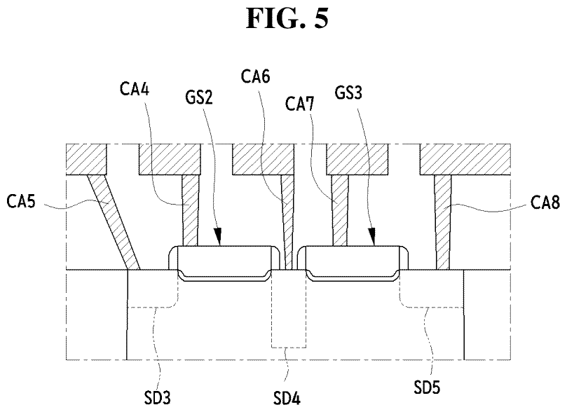

FIG. 5 is an enlarged view of a portion P2 of FIG. 4 according to some example embodiments. For convenience of explanation, differences from the contents explained in FIG. 4 will be mainly explained.

Referring to FIG. 5, the third source/drain region SD3 located at one end of the second gate structure GS2 may have a sixth depth D6 from the active pattern of the substrate 100. The fourth source/drain region SD4 located at one end of the third gate structure GS3 while being located at the other end of the second gate structure GS2 may have a seventh depth D7 from the active pattern of the substrate 100. The fifth source/drain region SD5 located at the other end of the third gate structure GS3 may have an eighth depth D8 from the active pattern of the substrate 100. In some example embodiments, the seventh depth D7 may be greater than the sixth depth D6 and the eighth depth D8.

In some example embodiments, the fourth source/drain region SD4 may have an upper doping region and a lower doping region having different types or concentrations of doped ions, like the first source/drain region SD1 of FIG. 3B.

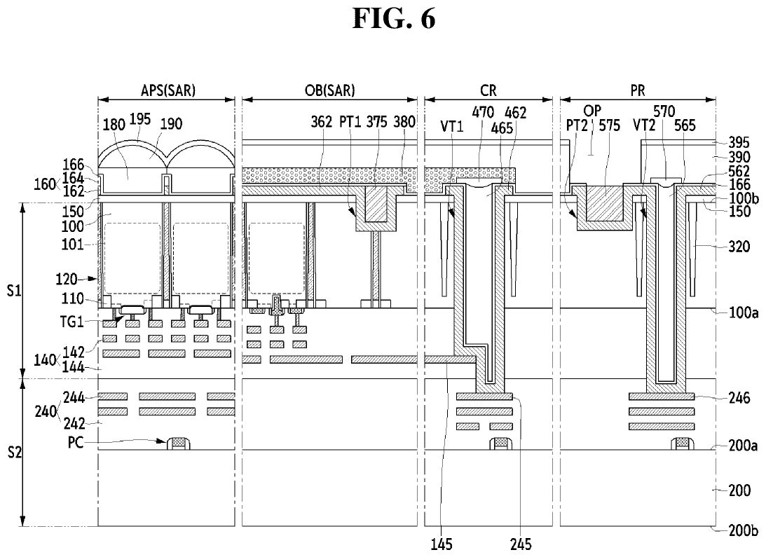

FIG. 6 is a cross-sectional view for explaining an image sensor according to some example embodiments.

Referring to FIG. 6, the image sensor according to some example embodiments includes a sensor array region SAR, a connecting region CR, and a pad region PR.

The sensor array region SAR may include a region corresponding to a pixel array. For example, a plurality of unit pixels arranged two-dimensionally (for example, in the form of a matrix such as a rectangular matrix, such as a square matrix) may be formed inside the sensor array region SAR.

The sensor array region SAR may include a photo-receiving region APS and a photo-shielding region OB. Active pixels that are supplied with light to generate active signals may be arranged in the photo-receiving region APS. Optical black pixels that generate optical black signals by shielding the light may be arranged in the photo-shielding region OB. The photo-shielding region OB may be formed, for example, along the periphery of the photo-receiving region APS, but this is merely an example.

In some example embodiments, the photoelectric conversion region 101 may be formed inside a part of the photo-shielding region OB, and may not be formed inside another part of the photo-shielding region OB. For example, the photoelectric conversion region 101 may be formed inside a part of the photo-shielding region OB adjacent to the photo-receiving region APS, but may not be formed inside another part of the photo-shielding region OB spaced apart from the photo-receiving region APS.

In some example embodiments, dummy pixels (not shown) may be formed in the photo-receiving region APS adjacent to the photo-shielding region OB.

The connecting region CR may be formed around the sensor array region SAR. The connecting region CR may be formed on one side of the sensor array region SAR, but this is only an example. Wirings are formed in the connecting region CR, and may be configured to transmit and receive electrical signals to and from the sensor array region SAR.

The pad region PR may be formed around the sensor array region SAR. The pad region PR may be formed to be adjacent to the edge of the image sensor according to some example embodiments, but this is merely an example. The pad region PR may be connected to an external device or the like and configured to transmit and receive electrical signals between the image sensor according to some example embodiments and the external device.

Although the connecting region CR is shown to be interposed between the sensor array region SAR and the pad region PR, this is merely an example. The placement of the sensor array region SAR, the connecting region CR, and the pad region PR may various as necessary or as desirable.

The first wiring structure 140 may include a first wiring pattern 142 in the sensor array region SAR and a second wiring pattern 144 in the connecting region CR. The first wiring pattern 142 may be electrically connected to the unit pixels of the sensor array region SAR. At least a part of the second wiring pattern 144 may be electrically connected to at least a part of the first wiring pattern 142. Accordingly, the second wiring pattern 144 may be electrically connected to the unit pixels of the sensor array region SAR.

The image sensor according to some example embodiments may include a second substrate 200 and a second wiring structure 240.

The second substrate 200 may be or may include bulk silicon or silicon-on-insulator (SOI). The second substrate 200 may be a silicon substrate, and/or may include other materials, for example, silicon germanium, indium antimonide, lead telluride, indium arsenide, indium phosphide, gallium arsenide or gallium antimonide. Alternatively, the second substrate 200 may be one in which an epitaxial layer is formed on a base substrate.

The second substrate 200 may include a third side 200a and a fourth side 200b that are opposite to each other. In some example embodiments to be described below, the third side 200a may be called a front side of the second substrate 200, and the fourth side 200b may be called a back side of the second substrate 200. In some example embodiments, the third side 200a of the second substrate 200 may be opposite to the first side 100a of the first substrate 100.

A peripheral circuit element PC may be formed on the third side 200a of the second substrate 200. The peripheral circuit element PC is electrically connected to the sensor array region SAR, and may transmit and receive electrical signals to and from each unit pixel of the sensor array region SAR.

The second wiring structure 240 may be formed on the third side 200a of the second substrate 200. For example, the second wiring structure 240 may include a second inter-wiring insulating film 242 and various wiring patterns 244, 245, and 246 inside the second inter-wiring insulating film 242. In FIG. 6, the number of layers, placement and the like of the wiring patterns 244, 245, and 246 are only examples, and example embodiments are not limited thereto.

At least some of the wiring patterns 244, 245, and 246 of the second wiring structure 240 may be connected to the peripheral circuit element PC. In some example embodiments, the second wiring structure 240 may include a third wiring pattern 244 in the sensor array region SAR, a fourth wiring pattern 245 in the connecting region CR, and a fifth wiring pattern 246 in the pad region PR. In some example embodiments, the fourth wiring pattern 245 may be an uppermost wiring among the plurality of wirings in the connecting region CR, and the fifth wiring pattern 246 may be an or may correspond to uppermost wiring among the plurality of wirings in the pad region PR.

The first wiring structure 140 and the second wiring structure 240 may be bonded to each other. For example, the first wiring structure 140 and the second wiring structure 240 may be bonded, for example, but not limited to, by a wafer bonding process and/or a through-via process.

The image sensor according to some example embodiments may include a first connecting structure 362, a second connecting structure 462, and a third connecting structure 562.

The first connecting structure 362 may be formed inside the photo-shielding region OB. The first connecting structure 362 may be formed on the surface insulating film 150 of the photo-shielding region OB. The first connecting structure 362 may be in contact with a part of the pixel isolation pattern 120. For example, a first pad trench PT1 that exposes the pixel isolation pattern 120 may be formed inside the first substrate 100 and the surface insulating film 150 of the photo-shielding region OB. The first connecting structure 362 is formed in the first pad trench PT1, and may be in contact with the pixel isolation pattern 120 of the photo-shielding region OB. In some example embodiments, the first connecting structure 362 may extend conformally along the profiles of the side face and the lower face of the first pad trench PT1.

The first connecting structure 362 may include, for example, but not limited to, at least one of titanium (Ti), titanium nitride (TiN), tantalum (Ta), tantalum nitride (TaN), tungsten (W), aluminum (Al), copper (Cu) or a combination thereof.

In some example embodiments, the first connecting structure 362 is electrically connected to a conductive material of the pixel isolation pattern 120, and may apply a negative (−) bias voltage.

In some example embodiments, a first pad 375 that fills the first pad trench PT1 may be formed on the first connecting structure 362. The first pad 375 may include, for example, but not limited to, at least one of tungsten (W), copper (Cu), aluminum (Al), gold (Au), silver (Ag), and alloys thereof.

In some example embodiments, the first protective film 166 may cover the first connecting structure 362 and the first pad 375. For example, the first protective film 166 may extend conformally along the profiles of the first connecting structure 362 and the first pad 375.

The second connecting structure 462 may be formed inside the connecting region CR. The second connecting structure 462 may be formed on the surface insulating film 150 of the connecting region CR. The second connecting structure 462 may electrically connect the first wiring structure 140 and the second wiring structure 240. For example, a first via trench VT1 that exposes the second wiring pattern 144 and the fourth wiring pattern 245 may be formed inside the connecting region CR. The second connecting structure 462 is formed inside the first via trench VT1, and may connect the second wiring pattern 144 and the fourth wiring pattern 245. In some example embodiments, the second connecting structure 462 may extend conformally along the profiles of the side face and the lower face of the first via trench VT1.

The second connecting structure 462 may include, for example, but not limited to, at least one of titanium (Ti), titanium nitride (TiN), tantalum (Ta), tantalum nitride (TaN), tungsten (W), aluminum (Al), copper (Cu) and a combination thereof. In some example embodiments, the second connecting structure 462 may be formed at the same level as the first connecting structure 362.

In some example embodiments, the first protective film 166 may cover the second connecting structure 462. For example, the first protective film 166 may extend along the profile of the second connecting structure 462.

In some example embodiments, a first filling insulating film 465 that fills the first via trench VT1 may be formed on the second connecting structure 462. The first filling insulating film 465 may include, for example, but not limited to, at least one of silicon oxide, aluminum oxide, tantalum oxide, and combinations thereof.

In some example embodiments, a first capping pattern 470 may be formed on the first filling insulating film 465. The first capping pattern 470 may cover the upper face of the first filling insulating film 465.

The third connecting structure 562 may be formed inside the pad region PR. The third connecting structure 562 may be formed on the surface insulating film 150 of the pad region PR. The third connecting structure 562 may electrically connect the second wiring structure 240 to an external device or the like. For example, a second pad trench PT2 may be formed inside the first substrate 100 of the pad region PR. The third connecting structure 562 may be formed inside the second pad trench PT2 and exposed. Further, a second via trench VT2 that exposes the fifth wiring pattern 246 may be formed inside the pad region PR. The third connecting structure 562 may be formed inside the second via trench VT2 and be in contact with the fifth wiring pattern 246. In some example embodiments, the third connecting structure 562 may extend conformally along the profiles of the side faces and the lower faces of the second pad trench PT2 and the second via trench VT2.

The third connecting structure 562 may include, for example, but not limited to, at least one of titanium (Ti), titanium nitride (TiN), tantalum (Ta), tantalum nitride (TaN), tungsten (W), aluminum (Al), copper (Cu) and a combination thereof. In some example embodiments, the third connecting structure 562 may be formed at the same level as the first connecting structure 362 and the second connecting structure 462.

In some example embodiments, a second filling insulating film 560 that fills the second via trench VT2 may be formed on the third connecting structure 562. The second filling insulating film 560 may include, for example, but not limited to, at least one of silicon oxide, aluminum oxide, tantalum oxide, and combinations thereof. In some example embodiments, the second filling insulating film 560 may be formed at the same level as the first filling insulating film 465.

In some example embodiments, a second pad 575 that fills the second via trench VT2 may be formed on the third connecting structure 562. The second pad 575 may include, for example, but not limited to, at least one of tungsten (W), copper (Cu), aluminum (Al), gold (Au), silver (Ag), and alloys and/or combinations thereof. In some example embodiments, the second pad 575 may be formed at the same level as the first pad 375.

In some example embodiments, the first protective film 166 may cover the third connecting structure 562. For example, the first protective film 166 may conformally extend along the profile of the third connecting structure 562. In some example embodiments, the first protective film 166 may expose the second pad 575.

In some example embodiments, a substrate isolation pattern 320 may be formed inside the first substrate 100. Although the substrate isolation pattern 320 is shown being formed only around the second connecting structure 462 and the third connecting structure 562, this is only an example. For example, the substrate isolation pattern 320 may be formed also around the first connecting structure 362. The substrate isolation pattern 320 may include, for example, but not limited to, at least one of silicon oxide, silicon nitride, silicon oxynitride, aluminum oxide, hafnium oxide, and combinations thereof.

In some example embodiments, the width of the substrate isolation pattern 320 may decrease from the second side 100b of the first substrate 100 toward the first side 100a of the first substrate 100. This may be due to the fact that the etching process for forming the substrate isolation pattern 320 is performed toward the second side 100b of the first substrate 100. For example, the substrate isolation pattern 320 may be a BDTI (Backside DTI) formed by a DTI (Deep Trench Isolation) process on the second side 100b of the first substrate 100. In some example embodiments, the substrate isolation pattern 320 may be spaced apart from the first side 100a of the first substrate 100.

In some example embodiments, a photo-shielding filter 380 may be formed on the first connecting structure 362 and the second connecting structure 462. For example, the photo-shielding filter 380 may be formed to cover at least a part of the first protective film 166 inside the photo-shielding region OB and the connecting region CR. The photo-shielding filter 380 may block light that is incident on the first substrate 100.

In some example embodiments, a third protective film 390 may be formed on the photo-shielding filter 380. For example, the third protective film 390 may be formed to cover at least a part of the first protective film 166 inside the photo-shielding region OB, the connecting region CR, and the pad region PR. In some example embodiments, the second protective film 195 may extend along the surface of the third protective film 390. The third protective film 390 may include, for example, but not limited to, a light-transmitting resin. In some example embodiments, the third protective film 390 may be formed at the same level as the micro lens 190.

In some example embodiments, the second protective film 195 and the third protective film 390 may expose the second pad 575. For example, an exposure opening OP that exposes the second pad 575 may be formed inside the second protective film 195 and the third protective film 390. Accordingly, the second pad 575 may be connected to an external device or the like, and configured to transmit and receive electrical signals between the image sensor according to some example embodiments and the external device. That is, the second pad 575 may be an I/O pad of the image sensor according to some example embodiments.

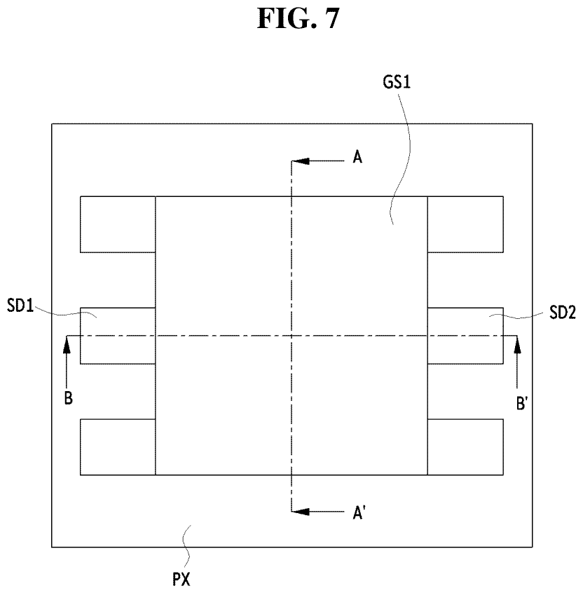

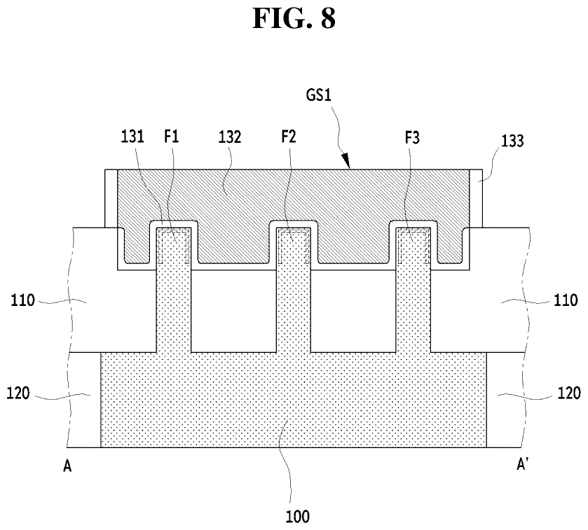

FIG. 7 is a plan view for explaining an image sensor according to some example embodiments. FIG. 8 is a schematic cross-sectional view taken along A-A′ of FIG. 7. The cross-sectional view taken along B-B′ of FIG. 7 is similar to FIG. 3A which is an enlarged view of FIG. 2. Therefore, for convenience of explanation, differences from the contents explained in FIG. 2 will be mainly explained.

Referring to FIG. 7, an image sensor according to some example embodiments may include a transistor having a multi-fin structure having a plurality of fins.

Referring to FIG. 8, the first gate structure GS1 may include a first fin F1, a second fin F2, and a third fin F3. The first fin F1, the second fin F2, and the third fin F3 may be surrounded by a first gate dielectric layer 131. The first fin F1, the second fin F2, and the third fin F3 may have a shape in which the first substrate 100 extends in the second direction (Z direction of FIG. 2). Because the first gate structure GS1 includes the first fin F1, the second fin F2, and the third fin F3, the area of the channel region may increase, and an image sensor with improved performance may be provided.

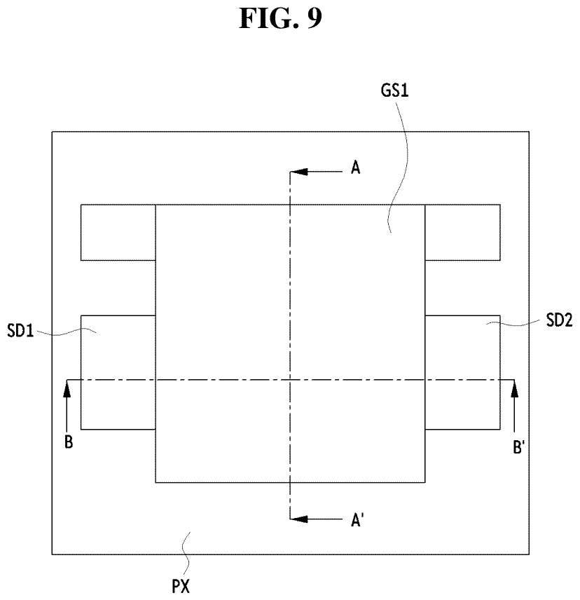

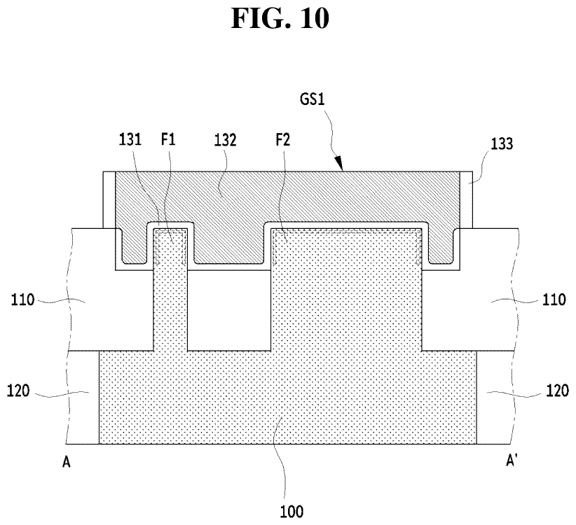

FIG. 9 is a plan view for explaining an image sensor according to some example embodiments. FIG. 10 is a schematic cross-sectional view taken along A-A′ of FIG. 9. The cross-sectional view taken along line B-B′ of FIG. 9 is similar to FIG. 3A which is an enlarged view of FIG. 2. For convenience of explanation, the differences from the contents explained in FIG. 2 will be mainly explained.

Referring to FIG. 9, an image sensor according to some example embodiments may include a transistor of a multi-fin structure having a plurality of fins.

Referring to FIG. 10, the first gate structure GS1 of the image sensor according to some example embodiments may include a first fin F1 and a second fin F2. The first fin F1 and the second fin F2 may be surrounded by the first gate dielectric layer 131. The first fin F1 and the second fin F2 may have a shape in which the first substrate 100 extends in the second direction (Z direction of FIG. 2). The widths of the first fin F1 and the second fin F2 in the third direction (Y direction of FIG. 2) may be different. Because the first gate structure GS1 includes the first fin F1 and the second fin F2, the area of the channel region may increase, and an image sensor with improved performance may be provided.

Although an image sensor including a transistor of a multi-fin structure has been explained in FIGS. 7 to 10, one or more of the shape, size, number, placement, and the like of the fins are merely an example and are not limited to those shown in the drawings.

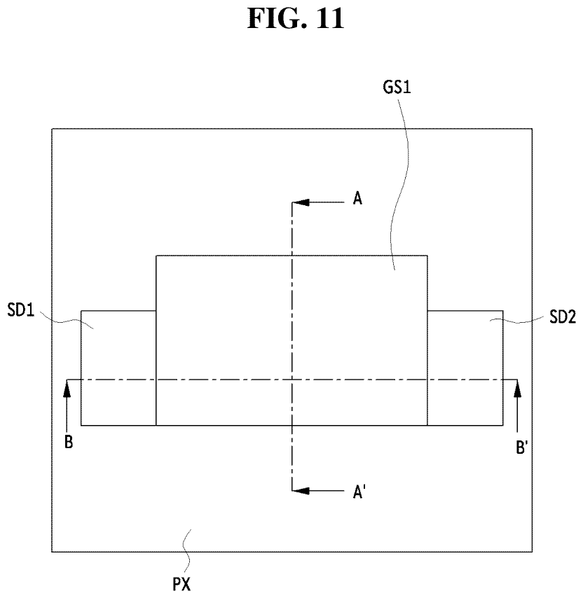

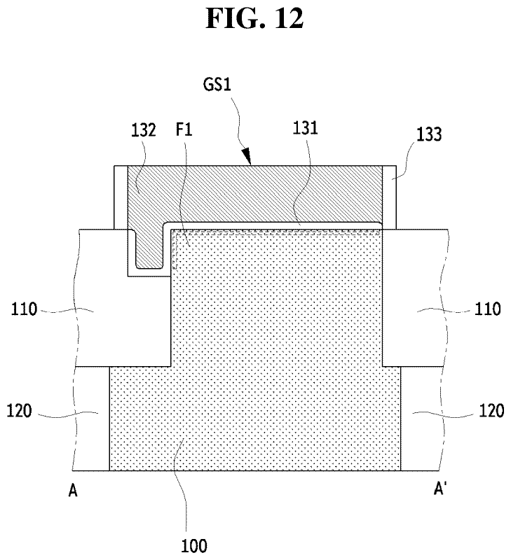

FIG. 11 is a plan view for explaining an image sensor according to some example embodiments. FIG. 12 is a schematic cross-sectional view taken along line A-A′ of FIG. 11. The cross-sectional view taken along line B-B′ of FIG. 11 is similar to FIG. 3A which is an enlarged view of FIG. 2. For convenience of explanation, differences from the contents explained in FIG. 2 will be mainly explained.

Referring to FIG. 11, an image sensor according to some example embodiments may include a transistor having a first gate structure GS1 that surrounds only a part of the first fin F1.

Referring to FIG. 12, the first gate structure GS1 that surrounds only a part of the first fin F1 may surround two of the three faces of the first fin F1. The first gate structure GS1 is deeply trenched to surround the first fin F1, thereby providing an image sensor having improved performance.

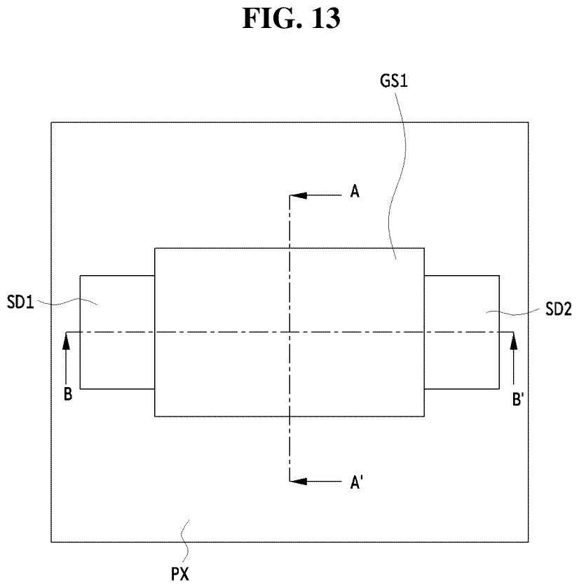

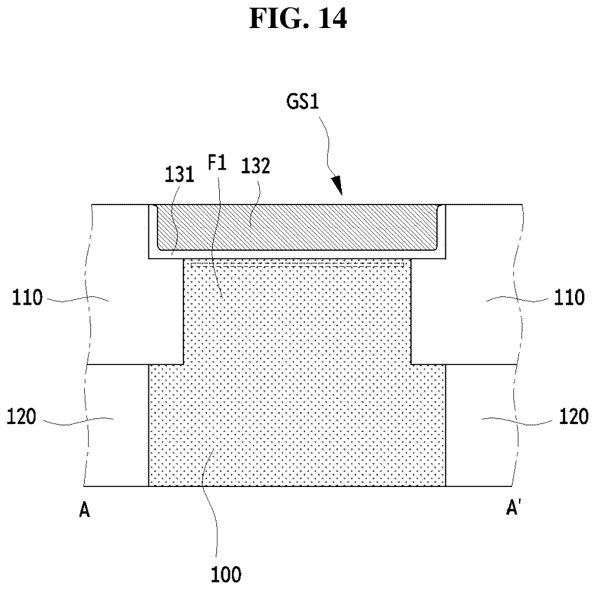

FIG. 13 is a plan view for explaining an image sensor according to some example embodiments. FIG. 14 is a schematic cross-sectional view taken along line A-A′ of FIG. 13.

Referring to FIG. 13, an image sensor according to some example embodiments may include a transistor having a first gate structure GS1 that surrounds only a part of the first fin F1.

Referring to FIG. 14, the first gate structure GS1 that surrounds only a part of the first fin F1 may surround one of the three faces of the first fin F1. The first gate structure GS1 may be disposed on one of the three faces of the first fin F1.

The first gate structure GS1 is deeply recessed to approach the first source/drain region SD1 and the second source/drain region, thereby providing an image sensor having improved performance.

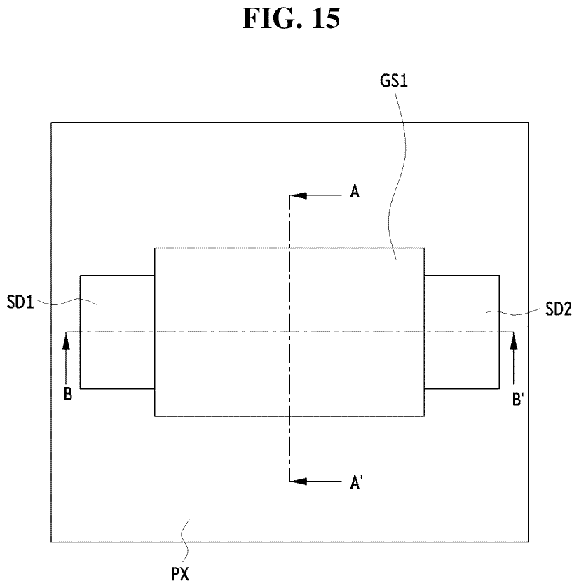

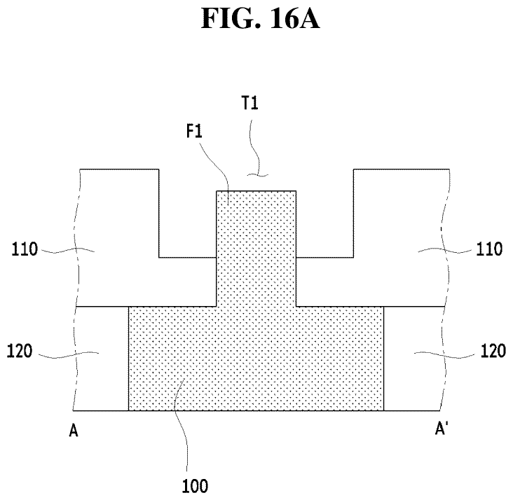

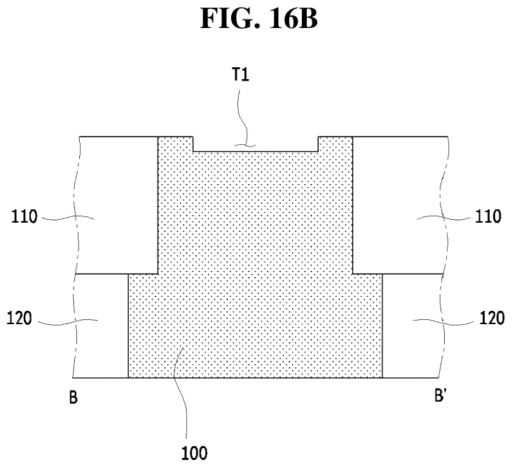

FIG. 15 is a plan view for explaining an image sensor according to some example embodiments. FIGS. 16 to 20 are cross-sectional views for explaining a method for fabricating an image sensor according to some example embodiments.

FIGS. 16A to 20B show cross-sections according to the process sequence of a region corresponding to the cross section of line A-A′ or line B-B′ of FIG. 13. For convenience of explanation, FIGS. 16A to 20B show only a part of the configuration in the image sensor, and the embodiment is not limited thereto.

Referring to FIGS. 16A and 16B, the element isolation pattern 110 and the pixel isolation pattern 120 may be provided on the substrate 100. The element isolation pattern 110 may be adjacent to (or in contact with) the first side 100a of the first substrate 100. The element isolation pattern 110 may define an active pattern AR inside the unit pixel PX adjacent to the first side 100a. The pixel isolation pattern 120 may be formed inside the first substrate 100. The pixel isolation pattern 120 may define a plurality of unit pixels PX inside the first substrate 100. For example, a deep trench (hereinafter, pixel isolation trench) that defines a plurality of unit pixels PX may be formed inside the first substrate 100.

The first side 100a of the substrate 100 may be etched, e.g., anisotropically etched, to form a first trench T1. Referring to FIG. 16A, the first trench T1 may be a space that surrounds the first fin F1 which partially protrudes from the substrate 100. Referring to FIG. 16B, the first trench T1 may be a shallow flat space formed by partially etching the substrate 100. The first trench T1 may be in a state in which the first substrate 100 is exposed.

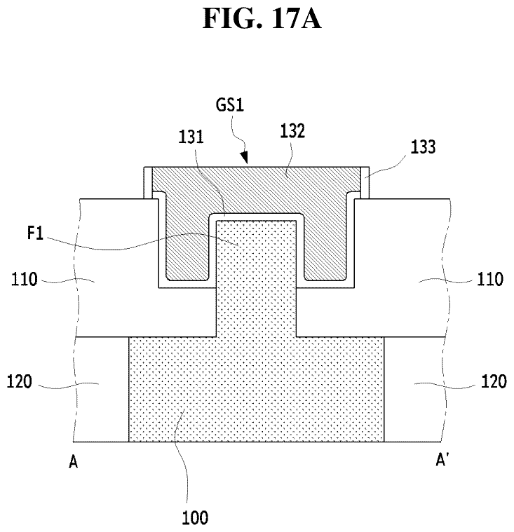

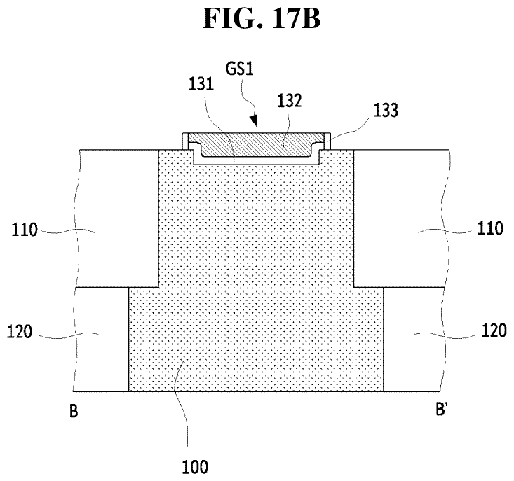

Referring to FIGS. 17A and 17B, the first gate structure GS1 may be formed. The first gate structure GS1 may include a gate dielectric film 131, a gate electrode film 132, and a gate spacer 133. The first gate structure may be a gate structure of a three-dimensional transistor.

Specifically, the gate dielectric film 131 may be formed on the first trench T1 in the state of FIGS. 16A and 16B. The first trench T1 may conformally cover the exposed portion of the first substrate 100.

The gate electrode film 132 may be formed on the formed gate dielectric film 131.

The gate electrode film 132 may be formed to cover the gate insulating film 120 over the upper face and both side walls of the first fin F1 of the first substrate 100. Referring to FIG. 17A, the gate electrode film 132 may extend along one direction (the Z direction of FIG. 2). Referring to FIG. 17B, the gate dielectric film 131 may extend partially into the first substrate 100. In some example embodiments, the gate dielectric film 131 may be formed on the first substrate 100, e.g., with an oxidation process and/or a deposition process.

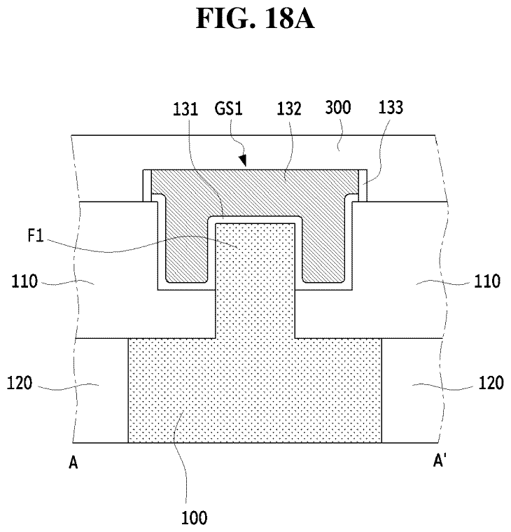

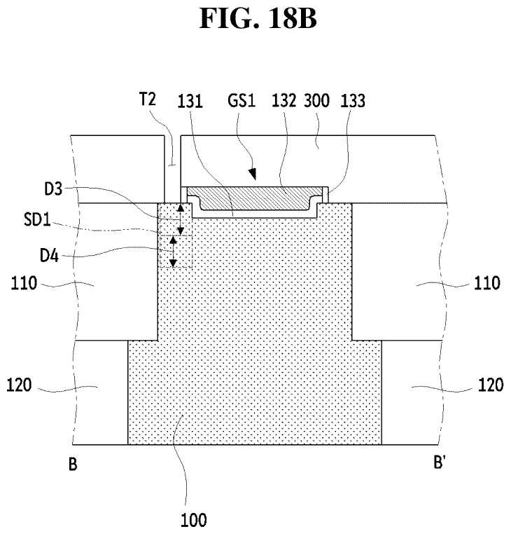

Referring to FIGS. 18A and 18B, a first mask 300 may be provided on the resultant product of FIGS. 17A and 17B. A photoresist patterning may be performed using the first mask 300. In some example embodiments, a litholess- or blank photoresist patterning may be performed without the first mask 300.

A second trench T2 may be formed in the first mask 300. Impurity ions may be implanted through the second trench T2, while performing the photoresist patterning. In some example embodiments, the impurity ions may be implanted after performing the photoresist patterning. The implanted impurity ions may form the first source/drain region SD1 at one end of the first gate structure GS1. The first source/drain region SD1 may be disposed on the first active pattern.

The first source/drain region SD1 may include an upper doped region and a lower doped region. Specifically, the upper doped region may be a region having a third depth D3 from the upper face of the active pattern. The lower doping region may be a region that has a fourth depth D4 greater than the third depth D3 on the basis of the upper face of the active pattern.

In some example embodiments, the upper doping region and the lower doping region may be doped with different types of ions. Different types of doped ions may refer to, for example, different types of ions inside the first type impurity. In some example embodiments, the upper doping region and the lower doping region may be doped with, e.g., implanted with, different concentrations of ions. Different concentrations of doped ions may refer to, for example, different concentrations in the same type of ions. In this case, the energy required or used to implant the impurity ions into the upper doping region and the lower doping region may be the same or different.

In some example embodiments, the upper doping region and the lower doping region may be doped with the same type and concentration of ions. The energy required to implant the impurity ions into the upper doping region and the lower doping region may be different.

In some example embodiments, the upper doping region and the lower doping region of the first source/drain region SD1 may be formed simultaneously in the process of FIGS. 18A and 17B. Also, in some example embodiments, the upper and lower doping regions of the first source/drain region SD1 of the first source/drain region SD1 may be formed sequentially.

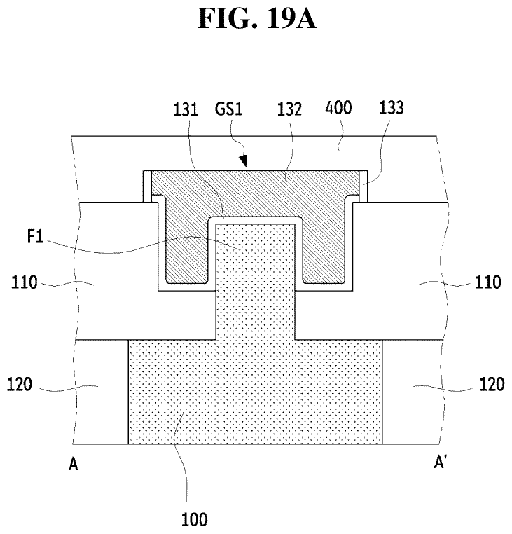

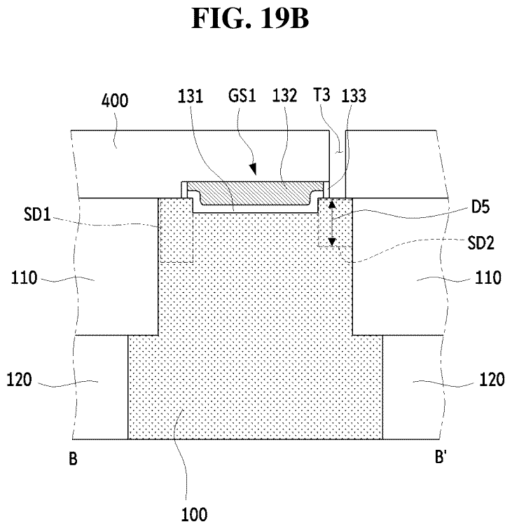

Referring to FIGS. 19A and 19B, the first mask 300 may be removed in FIGS. 18A and 17B, and a second mask 400 may be provided. The photoresist patterning may be performed using the second mask 400. In some example embodiments, a litholess photoresist or blank photoresist patterning may be performed without the second mask 400.

A third trench T3 may be formed in the second mask 400. Impurity ions may be implanted through the third trench T3, while performing the photoresist patterning. In some example embodiments, the impurity ions may be implanted after performing the photoresist patterning. The implanted impurity ions may form a second source/drain region SD2 at the other end of the first gate structure GS1. The second source/drain region SD2 may be disposed on the first active pattern.

The second source/drain region SD2 located at the other end of the first gate structure GS1 may be a region that has a fifth depth D5 from the upper face of the active pattern of the substrate 100. The fifth depth D5 of the second source/drain region SD2 from the first active pattern may be smaller than the fourth depth D4 of the upper doping region of the first source/drain region SD1.

Unlike FIGS. 18A-19B, in some example embodiments, the upper doped region of the first source/drain region SD1 and the second source/drain region SD2 may be formed simultaneously, and then the lower doped region of the first source/drain region SD1 may be formed.

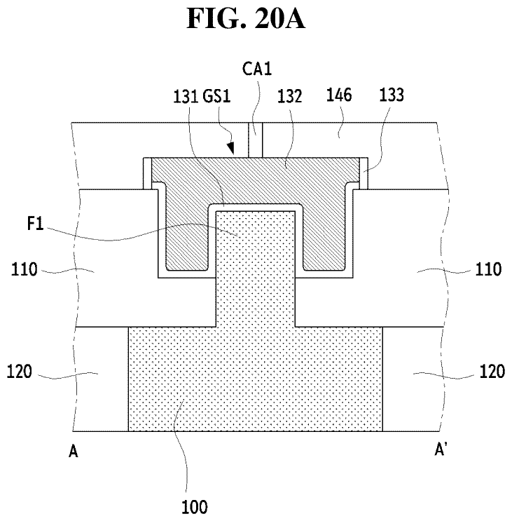

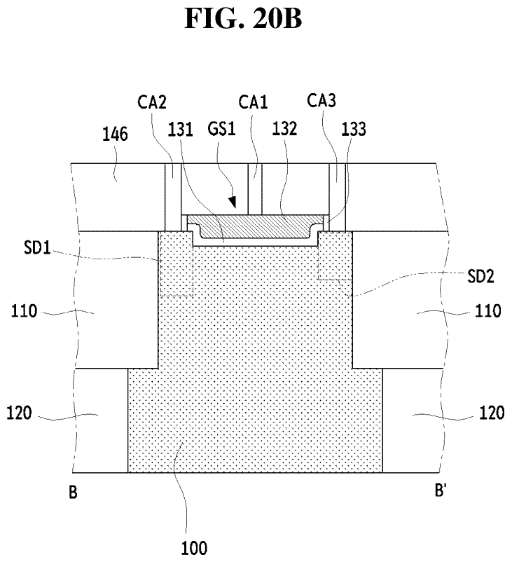

Referring to FIGS. 20A and 20B, the second mask 400 may be removed. An interlayer insulating film 146 that covers the first gate structure GS1 and the element isolation pattern 110 may be formed. The interlayer insulating film 146 may surround the first wiring structure 140. A first contact CA1, a second contact CA2, and a third contact CA3 that connect the first wiring structure 140, the first gate structure GS1, the first source/drain region SD1 and the second source/drain region SD2 may be formed. The first contact CA1, the second contact CA2 and the third contact CA3 may penetrate the interlayer insulating film 146, and be connected to the first wiring structure 140.

A method for fabricating the image sensor shown in FIG. 15 has been described referring to FIGS. 16 to 20B, but various modifications and/or alterations may be made within the scope of the technical concept to fabricate the image sensors shown in FIGS. 2 to 14 and various modified and altered image sensors.

Although some example embodiments have been described above with reference to the accompanying drawings, inventive concepts may not be limited to some example embodiments and may be implemented in various different forms. Those of ordinary skill in the technical field to which inventive concepts belongs will be able to understand that the present disclosure may be implemented in other specific forms without changing the technical idea or essential features. Therefore, it should be understood that the embodiments as described above are illustrative in all respects and are not restrictive. Additionally, example embodiments are not necessarily mutually exclusive with one another. For example, some example embodiments may include one or more features described with reference to one or more figures, and may also include one or more other features described with reference to one or more other figures.

What is claimed is:

1. An image sensor comprising:
a substrate;
a photoelectric conversion region inside the substrate;
a first active pattern protruding from a surface of the substrate;
an element isolation pattern covering at least a part of a side face of the first active pattern;
a first gate electrode on the first active pattern and the element isolation pattern, a lower face of the first gate electrode being lower than an upper face of the first active pattern;
a first source/drain region inside the first active pattern adjacent to one face of the first gate electrode; and
a second source/drain region inside the first active pattern adjacent to another face of the first gate electrode,
wherein a first depth of the first source/drain region is greater than a second depth of the second source/drain region from an upper face of the first active pattern.

2. The image sensor of claim 1,
wherein the photoelectric conversion region has a same conductivity type as the first source/drain region and the second source/drain region.

3. The image sensor of claim 2,
wherein the conductivity type is an n-type.

4. The image sensor of claim 1, further comprising:
a second gate electrode on the first active pattern and the element isolation pattern, and a lower face of the second gate electrode being lower than the upper face of the first active pattern; and
a third source/drain region inside the first active pattern,
wherein one face of the second gate electrode is adjacent to the third source/drain region inside the first active pattern, and another face of the second gate electrode is adjacent to the first source/drain region inside the first active pattern.

5. The image sensor of claim 4,
wherein the third source/drain region has a third depth on from the upper face of the first active pattern, and
the first depth is greater than the third depth.

6. The image sensor of claim 1, further comprising:
a second gate electrode on the first active pattern and the element isolation pattern, a lower face of the second gate electrode being lower than the upper face of the first active pattern; and
a third source/drain region inside the first active pattern,
wherein one face of the second gate electrode is adjacent to the third source/drain region inside the first active pattern, and
another face of the second gate electrode is adjacent to the second source/drain region inside the first active pattern.

7. The image sensor of claim 1, further comprising:
a second active pattern protruding from the surface of the substrate;
a third source/drain region inside the second active pattern; and
a fourth source/drain region inside the second active pattern,
wherein the first gate electrode is on the second active pattern and the element isolation pattern, and the lower face of the first gate electrode is lower than an upper face of the second active pattern,
the third source/drain region is inside the second active pattern adjacent to one face of the first gate electrode, and
the fourth source/drain region is inside the second active pattern adjacent to another face of the first gate electrode.

8. The image sensor of claim 7,
wherein a third depth of the third source/drain region is greater than a fourth depth of the fourth source/drain region, from the upper face of the second active pattern.

9. The image sensor of claim 7,
wherein a third depth of the fourth source/drain region is greater than a fourth depth of the third source/drain region, from the upper face of the second active pattern.

10. An image sensor comprising:
a substrate;
a photoelectric conversion region inside the substrate;
a first active pattern protruding from a surface of the substrate;
an element isolation pattern covering at least a part of a side face of the first active pattern;
a first gate electrode on the first active pattern and the element isolation pattern, a lower face of which is lower than an upper face of the first active pattern;
a first source/drain region inside the first active pattern adjacent to one face of the first gate electrode; and
a second source/drain region inside the first active pattern adjacent to another face of the first gate electrode,
wherein the first source/drain region comprises an upper doped region having a first depth from the upper face of the first active pattern, and a lower doped region having a second depth greater than the first depth from the upper face of the first active pattern, and
the upper doped region and the lower doped region are different from each other in at least one of type of majority impurities or concentration of majority impurities.

11. The image sensor of claim 10,
wherein the photoelectric conversion region has a same conductivity type as the first source/drain region and the second source/drain region.

12. The image sensor of claim 10, further comprising:
a second gate electrode on the first active pattern and the element isolation pattern, a lower face of which is lower than the upper face of the first active pattern; and
a third source/drain region inside the first active pattern,
wherein one face of the second gate electrode is adjacent to the third source/drain region inside the first active pattern, and
another face of the second gate electrode is adjacent to the first source/drain region inside the first active pattern.

13. The image sensor of claim 12,
wherein the third source/drain region has a third depth from the upper face of the first active pattern, and
the first depth is greater than the third depth.

14. The image sensor of claim 10, further comprising:
a second gate electrode on the first active pattern and the element isolation pattern, a lower face of which is lower than the upper face of the first active pattern; and
a third source/drain region inside the first active pattern,
wherein one face of the second gate electrode is adjacent to the third source/drain region inside the first active pattern, and
another face of the second gate electrode is adjacent to the second source/drain region inside the first active pattern.

15. The image sensor of claim 10, further comprising:
a second active pattern protruding from the surface of the substrate;
a third source/drain region inside the second active pattern; and
a fourth source/drain region inside the second active pattern,
wherein the first gate electrode is on the second active pattern and the element isolation pattern, and the lower face of the first gate electrode is lower than an upper face of the second active pattern,
the third source/drain region is inside the second active pattern adjacent to one face of the first gate electrode, and
the fourth source/drain region is inside the second active pattern adjacent to another face of the first gate electrode.

16. An image sensor comprising:
a substrate including a first side and a second side opposite to each other;
a pixel isolation pattern defining a unit pixel inside the substrate;
a photoelectric conversion region inside the unit pixel;
an element isolation pattern in contact with the first side of the substrate, and defining a first active pattern inside the unit pixel;
a first recess having a lower face lower than an upper face of the first active pattern, inside the element isolation pattern;
a first gate electrode filling the first recess on the first active pattern;
a first source/drain region inside the first active pattern adjacent to one face of the first gate electrode; and
a second source/drain region inside the first active pattern adjacent to another face of the first gate electrode,
wherein a first depth of the first source/drain region is greater than a second depth of the second source/drain region, from the upper face of the first active pattern.

17. The image sensor of claim 16,
wherein the photoelectric conversion region has a same conductivity type as the first source/drain region and the second source/drain region.

18. The image sensor of claim 16, further comprising:
a second recess having a lower face lower than the upper face of the first active pattern, inside the element isolation pattern;
a second gate electrode filling the second recess on the first active pattern; and
a third source/drain region inside the first active pattern,
wherein one face of the second gate electrode is adjacent to the third source/drain region existing inside the first active pattern, and
another face of the second gate electrode is adjacent to the first source/drain region existing inside the first active pattern.

19. The image sensor of claim 18,
wherein the third source/drain region has a third depth from the upper face of the first active pattern, and
the first depth is greater than the third depth.

20. The image sensor of claim 16, further comprising:
a second active pattern protruding from the first side of the substrate;
a third source/drain region inside the second active pattern; and
a fourth source/drain region inside the second active pattern,
wherein the first gate electrode is on the second active pattern and the element isolation pattern, and the lower face of the first gate electrode is lower than the upper face of the second active pattern,
the third source/drain region is inside the second active pattern adjacent to one face of the first gate electrode, and
the fourth source/drain region is inside the second active pattern adjacent to another face of the first gate electrode.
